(19) United States
(12) Patent Application Publication
(10) Pub. No.: US 2012/0042943 A1
(43) Pub. Date: Feb. 23, 2012

(54) BACKSHEET FOR A PHOTOVOLTAIC MODULE

(75) Inventor: Stephen Yau-Sang CHENG, Hong Kong (HK)

(73) Assignee: Du Pont Apollo Limited, Hong Kong (HK)

(21) Appl. No.: 13/191,481

(22) Filed: Jul. 27, 2011

Related U.S. Application Data
(60) Provisional application No. 61/375,881, filed on Aug. 23, 2010.

(51) Int. Cl. H01L 31/0216; B32B 15/04; B32B 27/36; B32B 5/00; B32B 27/08; B32B 27/40; B32B 27/30; B32B 15/08

(52) U.S. Cl. 136/256; 428/522; 428/457; 428/463; 428/339; 428/336; 428/520; 428/483; 428/501; 428/424.6; 428/423.1; 428/480; 428/424.4

(57) ABSTRACT

Disclosed herein is a backsheet for a photovoltaic member. The backsheet includes a weather-resistant layer, a first adhesive layer and an insulating layer. The weather-resistant layer contains chlorinated polyethylene, and the content of the chlorinated polyethylene is at least 50% by weight of the weather-resistant layer. The weather-resistant layer is situated at an outmost surface of the backsheet. The insulating layer may prevent an electric current generated by the photovoltaic member from leakage through the backsheet. The first adhesive layer is disposed between the weather-resistant layer and the insulating layer.

### RELATED APPLICATIONS

This application claims priority to U.S. Provisional Application Ser. No. 61/375,881, filed Aug. 23, 2010, which is herein incorporated by reference.

### BACKGROUND

1. Field of Invention

The present invention relates to an encapsulating sheet. More particularly, the present invention relates to a backsheet for a photovoltaic module.

2. Description of Related Art

Photovoltaic cells, also known as solar cells, are devices that convert light into electricity. Solar cells provide a number of advantages when compared to conventional energy sources. For example, solar cells produce electricity without pollution and do not require fossil fuel.

In general, the solar module generally comprises a rigid and transparent protective front panel such as glass, and a rear panel or sheet, which is typically called a backsheet. The front panel and backsheet encapsulate the solar cell(s) and provide protection from environmental damage.

A goal of the solar industry, however, is to have solar modules with an effective lifetime of decades, e.g. 20 years. Thus, the backsheet are concerned for providing adequate resistance to damage from impact and thermal shock, and also minimizing degradation from moisture, temperature, and ultraviolet radiation. A further concern of the backsheet is that it should be at a commercially acceptable cost.

A known backsheet comprising polyvinyl fluoride or other fluorinated polymers such as polyethylenetetrafluoroethylene or polyethylenechlorotrifluoroethylene is disclosed in the prior art. Unfortunately, fluorinated polymers are generally expensive. In addition to fluorinated polymers, other polymers used in the backsheet are also costly. For example, polyethyleneterephthate, which is used as a part of the backsheet, is undergone a costly orientation process to form an oriented film. Another example is polyimide, which is an expensive polymer as well. Therefore, there exists in this art a need of an improved backsheet, which would have a lower cost.

### SUMMARY

According to one aspect of the present disclosure, a backsheet for a photovoltaic member is provided. The backsheet includes a weather-resistant layer, a first adhesive layer and an insulating layer. The weather-resistant layer contains chlorinated polyethylene, and the content of the chlorinated polyethylene existed in the weather-resistant layer is at least 50% by weight of the weather-resistant layer. The insulating layer may prevent an electric current generated by the photovoltaic member from leakage through the backsheet. The first adhesive layer is disposed between the weather-resistant layer and the insulating layer.

According to another aspect of the present disclosure, a photovoltaic module is provided. The photovoltaic module includes a backsheet described above and a photovoltaic member disposed on the backsheet. The weather-resistant layer of the backsheet is situated at an outmost surface of the photovoltaic module.

According to still another aspect of the present disclosure, a backsheet containing no metal ingredients is provided. The backsheet is for a photovoltaic member, and consists essentially of a weather-resistant layer, an insulating layer and a first adhesive layer, in which the weather-resistant layer serves as an outmost layer. The weather-resistant layer comprises chlorinated polyethylene, and the content of the chlorinated polyethylene is at least 50% by weight of the weather-resistant layer. The insulating layer is capable of preventing an electric current generated by the photovoltaic member from leakage through the backsheet. The first adhesive layer is disposed between the weather-resistant layer and the insulating layer.

### BRIEF DESCRIPTION OF THE DRAWINGS

The invention can be more fully understood by reading the following detailed description of the embodiments, with reference made to the accompanying drawings as follows:

FIG. 1 is a cross-sectional view schematically illustrating a backsheet according to one embodiment of the present disclosure;

FIG. 2 is a cross-sectional view schematically illustrating a backsheet according to another embodiment of the present disclosure; and

FIG. 3 is a cross-sectional view schematically illustrating a photovoltaic module according to one embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

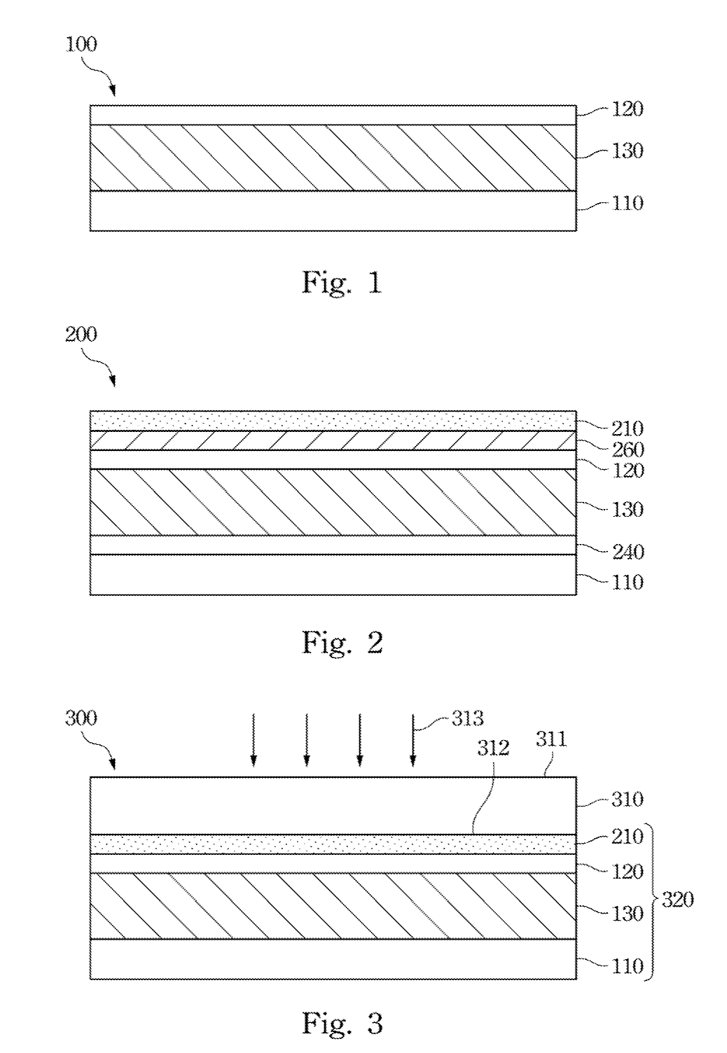

A backsheet for a photovoltaic member is disclosed hereinafter. FIG. 1 is a cross-sectional view schematically illustrating a backsheet 100 according to one embodiment of the present disclosure. As depicted in FIG. 1, the backsheet 100 includes a weather-resistant layer 110, an insulating layer 120 and a first adhesive layer 130.

The weather-resistant layer 110 may provide a function of weather resistance, and may be situated at an outmost surface of the backsheet 100, for example. The weather-resistant layer 110 comprises chlorinated polyethylene, and the content of the chlorinated polyethylene is at least 50% by weight of the weather-resistant layer 110. For example, the content of the chlorinated polyethylene may be 70%, 80%, 90% or 95% by weight of the weather-resistant layer 110. In one embodiment, the content of the chlorine existed in the chlorinated polyethylene may be at least 25 percent by weight of the chlorinated polyethylene, specifically about 25 percent to about 55 percent. In another embodiment, the thickness of the weather-resistant layer 110 may be greater than 1 μm, specifically greater than 10 μm, more specifically greater than 25 μm.

The weather-resistant layer 110 comprising chlorinated polyethylene may provide not only a function of weather resistance, but also a function of moisture resistance. The chlorinated polyethylene layer may exhibit excellent moisture resistance to a level of about 2-5 g-mil/(100 square inch×day). It is possible to eliminate the metal foil that is typically used as a moisture-barrier layer in the prior art. The backsheet 100 disclosed herein may be applied in a photovoltaic module that is not so sensitive to moisture, such as a polycrystalline silicon photovoltaic module. In these examples, the thickness of the weather-resistant layer 110 may be greater than 10 μm, specifically greater than 25 μm, more specifically about 50 μm to about 300 μm, and a satisfied resistance to moisture may be obtained. Furthermore, the backsheet 100 disclosed herein employs an inexpensive polymeric material (i.e. chlorinated polyethylene) and has a simple structure without a metal foil. Therefore, the backsheet 100 may be cost-effective.

In one embodiment, the weather-resistant layer 110 may further comprise at least one modifier such as stabilizers, pigments or fillers to modify the physical properties such as mechanical strength, durability and color of the weather-resistant layer 110. For example, about 0.1 wt % to about 50 wt %, based on the weight of the weather-resistant layer 110, of modifier may be added into the weather-resistant layer 110. More specifically, about 5% to about 30% of modifier may be added into the weather-resistant layer 110. In some embodiments, the weather-resistant layer 110 may have a multiple-layered structure, in which a pure chlorinated polyethylene layer is disposed. For instance, a layer of pure chlorinated polyethylene may be laminated on a chlorinated polyethylene layer which contains stabilizers, pigments or fillers.

In another embodiment, the chlorinated polyethylene in the weather-resistant layer 110 may be an acrylic acid grafted chlorinated polyethylene, a sulfonate grafted chlorinated polyethylene, or a maleic anhydride grafted chlorinated polyethylene, so that the original chemical property of the chlorinated polyethylene may be modified. In particular, grafting agents such as acrylic acid, sulfonate and maleic anhydrides may be employed to modify the molecular structure of the chlorinated polyethylene in the weather-resistant layer 110. However, the present disclosure is not limited on the above mentioned grafting agents.

The insulating layer 120 is disposed above the weather-resistant layer 110. In general, the photovoltaic member is positioned adjacent to the side of the insulating layer 120. The insulating layer 120 is operable to prevent an electric current generated by the photovoltaic member from leakage through the backsheet 100. For instance, the insulating layer 120 may be made from a material such as polyester, polyimide and polyethylene terephthalate. In some examples, the thickness of the insulating layer 120 is greater than 0.05 mm, specifically greater than 0.1 mm, more specifically greater than 0.2 mm.

The first adhesive layer 130 is disposed between the weather-resistant layer 110 and the insulating layer 120. The first adhesive layer 130 is operable to bond the weather-resistant layer 110 and the insulating layer 120 together. In one embodiment, the first adhesive layer 130 is in contact with the insulating layer 120 and the weather-resistant layer 110, as depicted in FIG. 1. In some examples, the first adhesive layer 130 may comprise at least one polymer such as a copolymer of ethylene and acrylic acid, a copolymer of ethylene and maleic anhydride, ethylene-vinyl acetate copolymer (EVA), polyvinyl butyral (PVB) or a two-part polyurethane. In examples, the first adhesive layer 130 may be about 0.01 mm to about 0.5 mm in thickness.

FIG. 2 is a cross-sectional view schematically illustrating a backsheet 200 according to another embodiment of the present disclosure. The backsheet 200 comprises a weather-resistant layer 110, an insulating layer 120 and a first adhesive layer 130, as described above, and further comprises a moisture-barrier layer 240.

The moisture-barrier layer 240 may provide a function to prevent moisture permeation, and is disposed between the weather-resistant layer 110 and the first adhesive layer 130. The moisture-barrier layer 240 may be made of a metallic material, polymeric material, inorganic material or a combination thereof. In one example, the moisture-barrier layer 240 is made of aluminum or stainless steel, and the weather-resistant layer 110 may directly contact the layer of aluminum or stainless steel. The chlorinated polyethylene in weather-resistant layer 110 exhibits an excellent adhesion with the metal foil such as aluminum or stainless steel. Therefore, an additional adhesive layer for connecting the moisture-barrier layer 240 with the weather-resistant layer 110 in the prior art is no longer required. In particular, a coating fluid containing chlorinated polyethylene (i.e. molten chlorinated polyethylene or a chlorinated polyethylene-solvent mixture) may be coated on the aluminum or stainless steel foil, and thus forming the weather-resistant layer 110. The backsheet 200 disclosed herein employs an inexpensive polymeric material (i.e. chlorinated polyethylene) and has a simple structure without an adhesive layer intervened between the moisture-barrier layer 240 and the weather-resistant layer 110. Therefore, the backsheet 200 according to one embodiment of the present disclosure is cost-effective.

In some examples, the moisture-barrier layer 240 may be made from a polymeric material such as polyvinylidene chloride (PVDC) or a copolymer of ethylene and vinyl alcohol (EVOH). The thickness of the moisture-barrier layer may range from about 1 μm to about 2000 μm.

In the case where the backsheet 200 comprises the moisture-barrier layer 240, the thickness of the weather-resistant layer 110 may be reduced to a level of less than 100 μm, specifically about 1 μm to about 50 μm. The backsheet 200 comprising moisture-barrier layer 240 disclosed herein may be applied in a photovoltaic module which is sensitive to moisture, such as an amorphous silicon photovoltaic module.

In one embodiment, the backsheet 200 may further comprise a second adhesive layer 260 and a tie layer 210, as depicted in FIG. 2. The second adhesive layer 260 is disposed on the insulating layer 120, and situated on a side opposite to the first adhesive layer 130. The second adhesive layer 260 is operable to bond the insulating layer 120 and tie layer 210 together. The material of the second adhesive layer 260 may be the same as or different from the first adhesive layer 130. Suitable materials for the second adhesive layer include, but are not limited to, ethylene-vinyl acetate copolymer (EVA), polyvinyl butyral (PVB), a copolymer of ethylene and acrylic acid, a copolymer of ethylene and maleic abhydride, and two-part polyurethane. In examples, the thickness of the second adhesive layer 260 may be in the range of about 0.01 mm to about 0.5 mm. Furthermore, the tie layer 210 is disposed on the second adhesive layer 260, and is capable of connecting to a photovoltaic member (not shown in FIG. 2). In some examples, the tie layer 210 is made from a copolymer of ethylene and vinyl acetate.

According to another aspect of the present disclosure, a photovoltaic module is disclosed. FIG. 3 is a cross-sectional view schematically illustrating a photovoltaic module 300 according to one embodiment of the present disclosure. Referring to FIG. 3, the photovoltaic module 300 comprises a photovoltaic member 310 and a backsheet 320, which may be any embodiment as described hereinbefore.

In one embodiment, the backsheet 320 may comprise in sequence a weather-resistant layer 110, a first adhesive layer 130, an insulating layer 120 and a tie layer 210, with the weather-resistant layer 110 being situated at an outmost surface. The weather-resistant layer 110, insulating layer 120 and first adhesive layer 130 may be the same as those described hereinbefore. The tie layer 210 is disposed onto the insulating layer 120, as depicted in FIG. 3.

The photovoltaic member 310 is positioned on the tie layer 210 of the backsheet 320. There is no specific limitation on the photovoltaic member 310 so long as it may convert light into electricity. In general, the photovoltaic member 310 has a light-receiving surface 311 and a back surface 312. Light 313 may be transmitted through the light-receiving surface 311 and then be absorbed by the photovoltaic member 310. When photovoltaic member 310 absorbs light, electron-hole pairs are generated therein, and the electron-hole pairs are separated by the electric field established in the photovoltaic member 310, and thus generating the electric current. The back surface 312 of the photovoltaic member 310 is adhered on the tie layer 210 of the backsheet 320 whereas the weather-resistant layer 110 is situated at an outmost surface of the photovoltaic module 300. The photovoltaic member 310 may be a flexible solar cell formed on a flexible substrate such as polyimide or stainless steel, or a rigid solar cell formed on a rigid substrate such as glass. In one example, the photovoltaic member 310 is a thin film solar cell. In other examples, the photovoltaic member 310 may be a single crystal solar cell or a polycrystalline solar cell, which is formed on a silicon substrate. In some examples, photovoltaic member 310 includes amorphous silicon and has a p-i-n structure composed of a p-type semiconductor, an intrinsic semiconductor and an n-type semiconductor (not shown). In other examples, the photovoltaic member 310 may include GaAs, CIGS, or CdTe.

While the foregoing is directed to embodiments of the present invention, other and further embodiments of the invention may be devised without departing from the basic scope thereof, and the scope thereof is determined by the claims that follow.

What is claimed is:

1. A backsheet for a photovoltaic member, comprising:
a weather-resistant layer comprising chlorinated polyethylene, wherein the chlorinated polyethylene has a content of at least 50% by weight of the weather-resistant layer;
an insulating layer for preventing an electric current generated by the photovoltaic member from leakage through the backsheet; and
a first adhesive layer disposed between the weather-resistant layer and the insulating layer.

2. The backsheet according to claim 1, further comprising a moisture-barrier layer disposed between the weather-resistant layer and the insulating layer.

3. The backsheet according to claim 2, wherein the moisture-barrier layer comprises aluminum or stainless steel.

4. The backsheet according to claim 3, wherein the weather-resistant layer is in direct contact with the moisture-barrier layer.

5. The backsheet according to claim 2, wherein the moisture-barrier layer comprises a polymeric material selected from the group consisting of polyvinylidene chloride (PVDC) and a copolymer of ethylene and vinyl alcohol (EVOH).

6. The backsheet according to claim 2, wherein the moisture-barrier layer has a thickness of about 1 μm to about 2000 μm.

7. The backsheet according to claim 1, wherein the chlorinated polyethylene has a chlorine content of at least 25 percent by weight of the chlorinated polyethylene.

8. The backsheet according to claim 1, wherein the weather-resistant layer further comprises at least one modifier selected from the group consisting of a stabilizer, a pigment, a filler and a coupling agent.

9. The backsheet according to claim 1, wherein the chlorinated polyethylene is acrylic acid grafted chlorinated polyethylene, sulfonate grafted chlorinated polyethylene or maleic anhydride grafted chlorinated polyethylene.

10. The backsheet according to claim 1, wherein the content of the chlorinated polyethylene is greater than 70% by weight of the weather-resistant layer.

11. The backsheet according to claim 1, wherein the content of the chlorinated polyethylene is greater than 90% by weight of the weather-resistant layer.

12. The backsheet according to claim 1, wherein the insulating layer comprises at least one material selected from the group consisting of polyester, polyimide and polyethylene terephthalate.

13. The backsheet according to claim 1, wherein the insulating layer has a thickness of greater than about 0.05 mm.

14. The backsheet according to claim 1, wherein the weather-resistant layer has a thickness of greater than about 1 μm.

15. The backsheet according to claim 1, wherein the weather-resistant layer has a thickness of greater than about 25 μm.

16. The backsheet according to claim 1, wherein the first adhesive layer comprises at least one material selected from the group consisting of copolymer of ethylene and acrylic acid, copolymer of ethylene and maleic abhydride, ethylene-vinyl acetate copolymer, polyvinyl butyral (PVB) and two-part polyurethane.

17. The backsheet according to claim 1, further comprising a second adhesive layer disposed on the insulating layer, with the second adhesive layer being situated on a side opposite to the first adhesive layer, and wherein the second adhesive layer comprises at least one material selected form the group consisting of copolymer of ethylene and acrylic acid, copolymer of ethylene and maleic abhydride, ethylene-vinyl acetate copolymer, polyvinyl butyral (PVB) and two-part polyurethane.

18. The backsheet according to claim 17, further comprising a tie layer disposed on the second adhesive layer, wherein the tie layer comprises a copolymer of ethylene and vinyl acetate.

19. A photovoltaic module, comprising:
a backsheet set forth in claim 1; and
a photovoltaic member disposed on the backsheet;
wherein the weather-resistant layer of the backsheet is situated at an outmost surface of the photovoltaic module.

20. A backsheet, which contains no metal ingredients, for a photovoltaic member, consisting essentially of:
a weather-resistant layer comprising chlorinated polyethylene and serving as an outmost layer, wherein the chlorinated polyethylene has a content of at least 50% by weight of the weather-resistant layer;
an insulating layer for preventing an electric current generated by the photovoltaic member from leakage through the backsheet; and
a first adhesive layer disposed between the weather-resistant layer and the insulating layer.
